(19) United States
(12) Patent Application Publication
(10) Pub. No.: US 2023/0133542 A1
(43) Pub. Date: May 4, 2023

(54) METHOD FOR PRODUCING POROUS BASE MATERIAL HAVING PORE WITH SURFACE MODIFIED AND POROUS BASE MATERIAL HAVING PORE WITH SURFACE MODIFIED

(71) Applicant: NITTO DENKO CORPORATION, Ibaraki-shi, Osaka (JP)

(72) Inventors: Mizuki YAMAMOTO, Ibaraki-shi, Osaka (JP); Tomoya KATO, Ibaraki-shi, Osaka (JP); Yukichi NAMIOKA, Ibaraki-shi, Osaka (JP)

(21) Appl. No.: 17/914,792

(22) PCT Filed: Jan. 19, 2021
(86) PCT No.: PCT/JP2021/001701

§ 371 Date: Sep. 27, 2022

(30) Foreign Application Priority Data
Mar. 27, 2020 (JP) 2020-058290

(51) Int. Cl. C23C 16/04; C23C 16/40; C23C 16/455; C23C 14/00; C08J 9/224

(52) U.S. Cl. CPC C23C 16/045; C23C 16/403; C23C 16/45525; C23C 14/0036; C08J 9/224; C08J 2323/28

(57) ABSTRACT

The present invention provides a method for producing a porous base material having a pore with a surface modified, the method being unlikely to limit a material of the porous base material and being suitable for controlling characteristics of the porous base material by introducing a polymer chain into a surface of a pore of the porous base material while inhibiting a change in a structure of the porous base material itself. The production method of the present invention includes: forming a base layer having a polymerization initiating group in such a manner as to cover a surface of a pore of a porous base material; and allowing a monomer group to be in contact with the base layer and thereby polymerizing the monomer group by the polymerization initiating group.

### TECHNICAL FIELD

The present invention relates to a method for producing a porous base material having a pore with a surface modified and a porous base material having a pore with a surface modified.

### BACKGROUND ART

A porous base material is used for various applications, such as a sound-transmitting membrane, a gas-permeable membrane, a separation membrane, an ion exchange membrane, a diaphragm, a catalyst, a liquid absorber, and a medical material, depending on its function. Usually, the function of the porous base material is determined based on a material and a structure of the porous base material.

It is known that by introducing a polymer chain into a surface of the porous base material, it is possible to enhance the function of the porous base material and add a new function to the porous base material. The introduction of a polymer chain can be carried out by, for example, allowing a radical to be generated on the surface of the porous base material and thereby polymerizing a monomer group by the radical. It is possible to generate the radical by irradiating the surface of the porous base material with an energy ray such as an ultraviolet ray, an electron ray, and a gamma ray, or plasma.

Patent Literatures 1 and 2 each disclose a method for introducing a polymer chain into a surface of a porous base material without using the energy ray or plasma. For example, Patent Literature 1 discloses to use a resin having a carbon-fluorine bond as a material of the porous base material as well as to use a catalyst to cut the carbon-fluorine bond and generate a radical.

### CITATION LIST

### Patent Literature

Patent Literature 1: JP 2017-88676 A

Patent Literature 2: JP 2004-331776 A

### SUMMARY OF INVENTION

### Technical Problem

When a surface of a porous base material is irradiated with plasma or an ultraviolet ray, a radical is generated only in the part irradiated with these and almost no radicals are generated inside the porous base material. Therefore, in order to generate a radical on a surface of a pore inside the porous base material, an energy ray, such as an electron ray and a gamma ray, having a relatively large energy is used. However, in the case where a porous base material containing a polymer compound is irradiated with the energy ray having a large energy, a principal chain of the polymer compound is cut depending on the polymer compound, and a mechanical strength of the porous base material is decreased significantly due to a change in a structure of the porous base material.

According to the methods of Patent Literatures 1 and 2, it is possible to introduce a polymer chain into a surface of a pore of a porous base material without using the energy ray. However, the methods of Patent Literatures 1 and 2 limit significantly a material that can be used for the porous base material.

Therefore, the present invention is intended to provide a method for producing a porous base material having a pore with a surface modified, the method being unlikely to limit a material of the porous base material and being suitable for controlling characteristics of the porous base material by introducing a polymer chain into a surface of a pore of the porous base material while inhibiting a change in a structure of the porous base material itself. In addition, the present invention is intended to provide a new porous base material having a pore with a surface modified.

### Solution to Problem

The present invention provides a method for producing a porous base material having a pore with a surface modified, including:

forming a base layer having a polymerization initiating group in such a manner as to cover a surface of a pore of a porous base material; and

allowing a monomer group to be in contact with the base layer and thereby polymerizing the monomer group by the polymerization initiating group.

In another aspect, the present invention further provides a porous base material having a pore with a surface modified, including:

a porous base material;

a base layer covering a surface of a pore of the porous base material; and

a polymer chain bonded to the base layer, wherein

the base layer contains at least one selected from the group consisting of a phosphorus atom and a silicon atom.

In another aspect, the present invention further provides a porous base material having a pore with a surface modified, including:

a porous base material;

a base layer covering a surface of a pore of the porous base material; and

a polymer chain bonded to the base layer, wherein

the polymer chain has a fluorine-containing hydrocarbon group.

In another aspect, the present invention further provides a porous base material having a pore with a surface modified, including:

a porous base material containing polytetrafluoroethylene;

a base layer covering a surface of a pore of the porous base material; and

a polymer chain bonded to the base layer, wherein

when a droplet that is composed of hexane and has a diameter of 5 mm is dropped on an outer surface of the porous base material having the pore with the surface modified, the droplet fails to penetrate into the outer surface within 30 seconds after being dropped.

### Advantageous Effects of Invention

The present invention can provide a method for producing a porous base material having a pore with a surface modified, the method being unlikely to limit a material of the porous base material and being suitable for controlling characteristics of the porous base material by introducing a polymer chain into a surface of a pore of the porous base material while inhibiting a change in a structure of the porous base material itself.

### BRIEF DESCRIPTION OF DRAWINGS

FIG. 1A is a diagram for explaining a production method according to one embodiment of the present invention.

FIG. 1B is a diagram for explaining a production method according to one embodiment of the present invention.

FIG. 1C is a diagram for explaining a production method according to one embodiment of the present invention.

### DESCRIPTION OF EMBODIMENTS

Hereinafter, the present invention will be described in detail. The following description is not intended to limit the present invention to a specific embodiment.

A method for producing a porous base material having a pore with a surface modified according to the present embodiment includes forming a base layer having a polymerization initiating group in such a manner as to cover a surface of a pore of a porous base material (step 1), and allowing a monomer group to be in contact with the base layer and thereby polymerizing the monomer group by the polymerization initiating group (step 2).

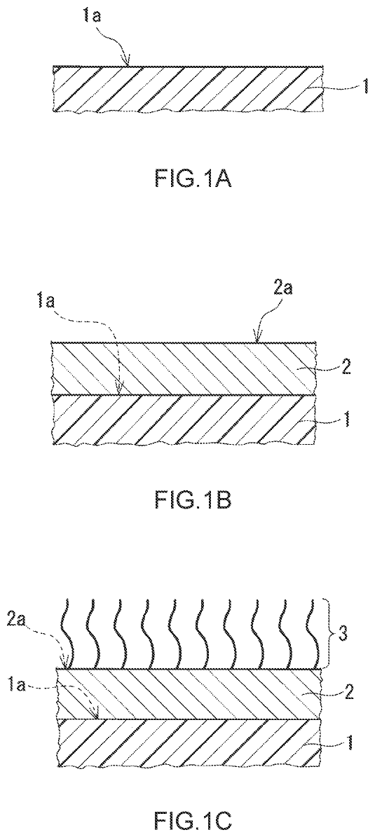

First, the step 1 will be explained. In the step 1, a base layer 2 is formed in such a manner as to cover a surface 1a of a pore of a porous base material 1 as shown in FIGS. 1A and 1B. FIGS. 1A and 1B each are a partially enlarged cross-sectional view of the pore of the porous base material 1. In FIGS. 1A and 1B, a cross-section of the surface 1a of the pore is illustrated as a straight line for simplification, but the shape of the surface 1a is not limited to this. The surface 1a of the pore is, in other words, a surface facing a pore inside the porous base material 1. In the present description, a surface that determines an outer shape of the porous base material 1 is referred to as an outer surface of the porous base material 1 in order to distinguish it from the surface 1a in some cases. The base layer 2 may cover the surface 1a of the pore entirely, or may cover the surface 1a of the pore partially. The base layer 2 may cover not only the surface 1a of the pore but also the outer surface of the porous base material 1.

In the present embodiment, a material and a structure of the porous base material 1 are not particularly limited. The porous base material 1 may contain an organic material, an inorganic material, or both an organic material and an inorganic material. Examples of the organic material contained in the porous base material 1 include a resin such as a hydrophobic resin and a hydrophilic resin. For example, the porous base material 1 may contain a hydrophobic resin. In the present description, the “hydrophobic resin” means a resin with a water content of 0.1% or less, and the “hydrophilic resin” means a resin with a water content exceeding 0.1%. The “water content” means a ratio of a difference between a weight of the resin containing water and a weight of the resin dried with respect to the weight of the resin dried. The “weight of the resin dried” is a value obtained by weighing the resin at the time when the resin is dried by being left at rest for 2 hours or more under an atmosphere at 60° C. The “weight of the resin containing water” is a value obtained by maintaining the state in which the above-mentioned resin dried is immersed for 2 hours or more in water kept warmed at 30° C. and then weighing this resin. The procedure that “the resin is dried by being left at rest for 2 hours or more under an atmosphere at 60° C. ” is continued until reaching a state in which no change occurs in the weight of the resin. The duration for which the resin is left at rest is not particularly limited as long as it is 2 hours or more and the state in which no change occurs in the weight of the resin is reached. The duration may be 2 hours or may be 3 hours. The “state in which no change occurs in the weight of the resin” means, for example, that a difference between a weight Wₜ of the resin dried by being left at rest for a predetermined duration of 2 hours or more (t hours) under an atmosphere at 60° C. and a weight W_{t+0.5} of the resin dried by being left at rest for another 30 minutes (t+0.5 hours) is within a range of ±0.5% of the weight Wₜ. The procedure of “maintaining the state in which the resin is immersed for 2 hours or more in water kept warmed at 30° C.” is continued until reaching a state in which no change occurs in the weight of the resin in accordance with the same criterion as the one mentioned above.

Examples of the hydrophobic resin include: a fluororesin such as polytetrafluoroethylene (PTFE), polyvinylidene fluoride (PVDF), an ethylene-polytetrafluoroethylene copolymer (ETFE), and perfluoroalkoxy alkane (PFA); a polyolefin resin such as polyethylene (PE) and polypropylene (PP); a polystyrene resin; and a rubber resin. Preferably, the porous base material 1 contains PTFE as the hydrophobic resin.

Examples of the hydrophilic resin include: a polyimide resin; a polyetherimide resin; a polyetheretherketone resin; a polyether sulphone resin; a polyethylene terephthalate resin; a polycarbonate resin; a polyamide resin such as nylon; a cellulosic resin; an epoxy resin; a (meth)acrylate resin such as polymethyl (meth)acrylate; and a polyvinyl alcohol resin such as polyvinyl alcohol (PVA) and an ethylene-vinylalcohol copolymer (EVOH). In the present description, (meth)acrylic acid means acrylic acid or methacrylic acid.

Examples of the inorganic material include glass, a metal, a metal oxide, and an alloy.

The porous base material 1 may include a fluororesin, particularly PTFE, as a main component. Preferably, the porous base material 1 is composed substantially of a fluororesin. In the present description, the “main component” means a component having a largest content in the porous base material 1 on weight ratio basis. The term “being composed substantially of a material” means that another component that changes an essential characteristic of the mentioned material is excluded. However, the porous base material 1 may contain an impurity other than the fluororesin.

Example of a shape of the porous base material 1 include a membranous shape and a particulate shape. Specific embodiments of the porous base material 1 with a membranous shape include a film, a woven fabric, and a nonwoven fabric. In the case where the porous base material 1 has a membranous shape, the porous base material 1 has a thickness of 1 to 1000 μm, for example. A pore included in the porous base material 1 has a shape that is not particularly limited. The pore is open at the outer surface of the porous base material 1, for example. The porous base material 1 may have a continuous pore formed continuously in three dimensions, or may have an independent pore. The porous base material 1 may have a through hole penetrating the porous base material 1. For example, the through hole may extend in a thickness direction of the porous base material 1.

The porous base material 1 has an average pore diameter of 0.01 to 100 μm, for example. The average pore diameter of the porous base material 1 can be measured by a method in accordance with American Society for Testing and Materials (ASTM) F316-86.

The porous base material 1 has a porosity of 10% to 90%, for example. The porosity of the porous base material 1 can be calculated by substituting a weight W (g), a volume V (cm³), and a true density D (g/cm³) of the porous base material 1 into the equation below.

Porosity (%)={1−(W/(V·D))}×100

A BET (Brunauer-Emmett-Teller) specific surface area, obtained by nitrogen gas adsorption, of the porous base material 1 is not particularly limited, and it is 0.01 to 100 m²/g, for example.

The base layer 2 can be formed by the following method, for example. First, an inorganic layer containing an inorganic material is formed in such a manner as to cover the surface 1a of the pore of the porous base material 1. The inorganic layer contains, for example, at least one selected from the group consisting of Al₂O₃, SiO₂, and TiO₂ as the inorganic material. The inorganic layer has a thickness that is not particularly limited, and it is 1 to 200 nm, for example.

The inorganic layer may be composed of one layer or may be composed of a plurality of layers. For example, the inorganic layer may be provided with a first layer that contains SiO₂ as a main component and a second layer that is disposed on the first layer and contains Al₂O₃ as a main component.

The inorganic layer can be formed by a physical deposition method or a chemical deposition method, for example. As the physical deposition method, a spattering method, specifically a radio frequency (RF) magnetron sputtering method can be mentioned. The spattering method is suitable for forming the inorganic layer on the outer surface of the porous base material 1 and on the surface 1a of the pore that is near the outer surface of the porous base material 1. In other words, the spattering method is suitable for forming the inorganic layer that covers the outer surface of the porous base material 1 entirely while covering the surface 1a of the pore partially. The spattering method can be carried out using a commercially available vacuum sputtering apparatus, for example.

As the chemical deposition method, an atomic layer deposition (ALD) method can be mentioned, for example. The ALD method is suitable for forming the inorganic layer that covers the outer surface of the porous base material 1 and the surface 1a of the pore of the porous base material 1 entirely.

In the ALD method, a source gas (a precursor gas of the inorganic material) and an oxidizing gas are introduced alternately into a container in which the porous base material 1 is put. Thereby, the source gas is oxidized on the surface 1a of the pore of the porous base material 1 and the inorganic material is deposited thereon. The deposition of the inorganic material forms the inorganic layer. The source gas can be suitably selected depending on a composition of the inorganic layer. For example, in the case where the inorganic layer contains Al₂O₃, a gaseous organoaluminium compound can be used as the source gas. Examples of the organoaluminium compound include trimethylaluminum and triisobutylaluminum. In the case where the inorganic layer contains SiO₂, a gaseous organosilicon compound can be used as the source gas. Examples of the organosilicon compound include bisdiethylaminosilane. Examples of the oxidizing gas include water vapor. Into the container in which the porous base material 1 is put, an inert gas, such as a nitrogen gas, may be introduced besides the source gas and the oxidizing gas.

In the ALD method, the porous base material 1 may be heated. In this case, the porous base material 1 has a temperature of 30° C. to 300° C., for example.

Specifically, the ALD method includes step i of introducing the source gas into the container in which the porous base material 1 is put, step ii of discharging the source gas from the container, step iii of introducing the oxidizing gas into the container, and step iv of discharging the oxidizing gas from the container. In the steps ii and iv, an inert gas may be introduced into the container after the respective gases are discharged from the container. In the ALD method, the cycle of the steps i to iv is repeated 1 to 1000 times, for example. It is possible to adjust the thickness of the inorganic layer by the number of the cycles of the steps i to iv.

Next, the polymerization initiating group is introduced into the inorganic layer to form the base layer 2. The polymerization initiating group is not particularly limited, and it is preferably a polymerization initiating group that can initiate living radical polymerization. Examples of the polymerization initiating group include a halogen group, an azo group, and a nitroxide group. The halogen group is F, Cl, Br, or I, for example, and it is preferably Br.

A method for introducing the polymerization initiating group into the inorganic layer is not particularly limited. For example, it is possible to introduce the polymerization initiating group into the inorganic layer by allowing at least one selected from the group consisting of a phosphorus compound P1 including the polymerization initiating group and a silicon compound S1 including the polymerization initiating group to react with a hydroxyl group present on a surface of the inorganic layer.

The phosphorus compound P1 includes a phosphate group or a phosphonate group, for example. The phosphorus compound P1 including a phosphate group is represented by formula (1) below, for example.

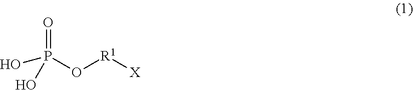

In the formula (1), R¹ is a divalent hydrocarbon group that may have a substituent. As for R¹, the number of carbon atoms that the hydrocarbon group has is not particularly limited, and it is 1 to 15, for example, and it is preferably 3 to 10. The hydrocarbon group may be linear or may be branched. The substituent of the hydrocarbon group may include a hetero atom such as a nitrogen atom and an oxygen atom. Examples of the substituent of the hydrocarbon group include an amide group. R¹ may be a divalent group represented by formula (2) below.

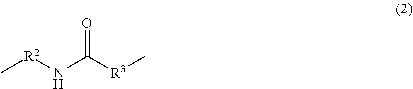

In the formula (2), R² is a divalent hydrocarbon group that may have a substituent. As for R², the number of carbon atoms that the hydrocarbon group has is not particularly limited, and it is 1 to 8, for example, and it is preferably 1 to 4. The hydrocarbon group may be linear or may be branched. Specific examples of R² include a methylene group and an ethylene group. R³ is a divalent hydrocarbon group that may have a substituent. As the hydrocarbon group that is R³, the hydrocarbon groups stated above for R² can be mentioned. Specific examples of R³ include a propane-2,2-diyl group.

In the formula (1), X is a polymerization initiating group. As the polymerization initiating group, the polymerization initiating groups stated above can be mentioned. A specific example of the phosphorus compound P1 including a phosphate group is (2-bromo-2-methyl-propionylamino)ethyl phosphoric monoester.

The phosphorus compound P1 including a phosphonate group is represented by formula (3) below, for example.

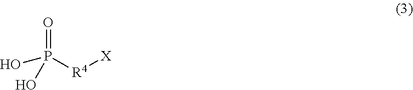

In the formula (3), R⁴ is a divalent hydrocarbon group that may have a substituent. As for R⁴, the number of carbon atoms that the hydrocarbon group has is not particularly limited, and it is 1 to 15, for example, and it is preferably 3 to 10. The hydrocarbon group may be linear or may be branched. The substituent of the hydrocarbon group may include a hetero atom such as a nitrogen atom and an oxygen atom. Examples of the substituent of the hydrocarbon group include an ester group. R⁴ may be a divalent group represented by formula (4) below.

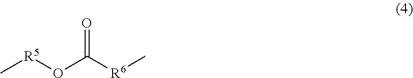

In the formula (4), R⁵ is a divalent hydrocarbon group that may have a substituent. As for R⁵, the number of carbon atoms that the hydrocarbon group has is not particularly limited, and it is 1 to 8, for example, and it is preferably 1 to 4. The hydrocarbon group may be linear or may be branched. Specific examples of R⁵ include a methylene group, an ethylene group, and a propane-1,3-diyl group. R⁶ is a divalent hydrocarbon group that may have a substituent. As the hydrocarbon group that is R⁶, the hydrocarbon groups stated above for R⁵ can be mentioned, for example. Specific examples of R⁶ include a propane-2,2-diyl group.

In the formula (3), X is a polymerization initiating group. As the polymerization initiating group, the polymerization initiating groups stated above can be mentioned. The phosphorus compound P1 represented by the formula (3) includes a carbon-phosphorus bond. A specific example of the phosphorus compound P1 including a phosphonate group is (3-((2-bromo-2-methylpropanoyl)oxy)propyl)phosphonate.

The silicon compound S1 includes a hydrolytic group and a hydrocarbon group, for example, and it is preferably represented by formula (5) below. The silicon compound S1 is, for example, a compound obtained by introducing a polymerization initiating group into a known silane coupling agent.

SiYn(R⁷—X)₄₋ₙ (5)

In the formula (5), each Y is independently a hydrolytic group. Examples of the hydrolytic group include a chloro group and an alkoxy group. The number of carbon atoms that the alkoxy group has is not particularly limited, and it is 1 to 3, for example. Specific examples of the alkoxy group include a methoxy group and an ethoxy group.

In the formula (5), each R⁷ is independently a divalent hydrocarbon group that may have a substituent. As for R⁷, the number of carbon atoms that the hydrocarbon group has is not particularly limited, and it is 1 to 15, for example, and it is preferably 3 to 10. The hydrocarbon group may be linear or may be branched. The substituent of the hydrocarbon group may include a hetero atom such as a nitrogen atom and an oxygen atom. Examples of the substituent of the hydrocarbon group include an ester group. R⁷ may be a divalent group represented by the formula (4) mentioned above.

In the formula (5), each X is independently a polymerization initiating group. As the polymerization initiating group, the polymerization initiating groups stated above can be mentioned. The letter n refers to an integer of 1 to 3 and it is preferably 3. The silicon compound S1 represented by the formula (5) includes a carbon-silicon bond. Specific examples of the silicon compound S1 include 3-(trichlorosilyl)propyl 2-bromo-2-methylpropanoate, 3-(trimethoxysilyl)propyl 2-bromo-2-methylpropanoate, and 3-(triethoxysilyl)propyl 2-bromo-2-methylpropanoate.

The reaction between at least one selected from the group consisting of the phosphorus compound P1 and the silicon compound S1 and the hydroxyl group present on the surface of the inorganic layer can be made by the following method, for example. First, a solution containing at least one selected from the group consisting of the phosphorus compound P1 and the silicon compound S1 is prepared. The porous base material 1 is immersed in this solution. Thereby, the solution enters into a pore of the porous base material 1 and the phosphorus compound P1 or the silicon compound S1 is in contact with the inorganic layer. As the result of the contact of the phosphorus compound P1 or the silicon compound S1 with the inorganic layer, a reaction between the phosphorus compound P1 or the silicon compound S1 and the hydroxyl group present on the surface of the inorganic layer proceeds.

In the case where the phosphorus compound P1 represented by the formula (1) is allowed to react with the hydroxyl group present on the surface of the inorganic layer, the surface, into which the polymerization initiating group has been introduced, of the inorganic layer is represented by formula (6) below, for example. In the formula (6), R¹ and X are identical to those mentioned above for the formula (1).

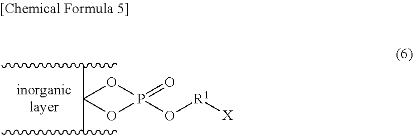

The method for introducing the polymerization initiating group into the inorganic layer is not limited to the above-mentioned method. The polymerization initiating group may be introduced into the inorganic layer by the following method, for example. First, at least one selected from the group consisting of a phosphorus compound P2 having a functional group F such as a primary amino group and a silicon compound S2 having the functional group F is allowed to react with the hydroxyl group present on the surface of the inorganic layer. Thereby, the functional group F is introduced into the surface of the inorganic layer. A specific example of the phosphorus compound P2 is O-phosphorylethanolamine. Next, a compound C including the polymerization initiating group and a group capable of reacting with the functional group F is allowed to be in contact with the surface of the inorganic layer. Thereby, the compound C is allowed to react with the functional group F present on the surface of the inorganic layer. Thereby, the polymerization initiating group can be introduced into the inorganic layer. In the compound C, the group capable of reacting with the functional group F is not particularly limited. For example, in the case where the functional group F is a primary amino group, an acyl halide group, such as an acyl bromide group, can be mentioned as the group capable of reacting with the functional group F. A specific example of the compound C is 2-bromoisobutylbromide.

According to the method for producing the base layer 2 of the present embodiment, there is a tendency that a density of the polymerization initiating group with respect to a surface of the porous base material 1 can be adjusted to be high. Per square nanometer of the surface of the porous base material 1, 0.1 or more of the polymerization initiating groups are present, for example, and preferably 0.5 or more of the polymerization initiating groups are present, and more preferably 1.0 or more of the polymerization initiating group are present, and still more preferably 1.5 or more of the polymerization initiating groups are present. The upper limit of the number of the polymerization initiating groups per square nanometer of the surface of the porous base material 1 is not particularly limited and it is 5, for example. The number of the polymerization initiating groups per square nanometer of the surface of the porous base material 1 can be calculated from the BET (Brunauer-Emmett-Teller) specific surface area, obtained by nitrogen gas adsorption, of the porous base material 1 with the base layer 2 formed thereon and the number of the polymerization initiating groups included in the base layer 2. The number of the polymerization initiating groups included in the base layer 2 can be measured by an elemental analysis on the base layer 2. For example, in the case where the polymerization initiating group is Br, the number of the polymerization initiating groups included in the base layer 2 can be determined by the following method. First, the porous base material 1 with the base layer 2 formed thereon is placed on a ceramic board. Next, the porous base material 1 is burned using an automatic specimen burner. A gas generated at that time is collected in an absorbing solution. As necessary, water is added to this absorbing solution to adjust a concentration thereof. The absorbing solution is subject to a quantitative analysis by ion chromatograph (IC). Thereby, the number of the polymerization initiating groups (Br) included in the base layer 2 can be determined.

Next, the step 2 will be explained. In the step 2, the monomer group is allowed to be in contact with the base layer 2 and thereby the monomer group is polymerized by the polymerization initiating group included in the base layer 2. Thereby, a polymer chain 3 is introduced into the base layer 2 as shown in FIG. 10. In other words, the polymer chain 3 is introduced into the surface 1a of the pore of the porous base material 1. Specifically, the polymer chain 3 is bonded to a surface 2a of the base layer 2 and extends in a thickness direction of the base layer 2. In the case where the base layer 2 covers the outer surface of the porous base material 1 as well, the polymer chain 3 is introduced also into the outer surface of the porous base material 1.

The monomer group includes a radical polymerizable monomer, for example. Examples of the radical polymerizable monomer include (meth)acrylic ester, (meth)acrylic acid, (meth)acrylamide, a styrene derivative, olefin, halogenated olefin, vinyl ester, vinyl alcohol, and nitrile.

The (meth)acrylic ester is represented by formula (7) below, for example.

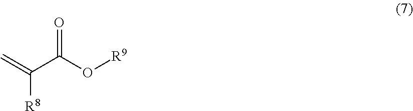

In the formula (7), R⁹ is a hydrogen atom or a methyl group. R⁹ is a hydrocarbon group that may have a substituent. As for R⁹, the number of carbon atoms that the hydrocarbon group has is not particularly limited, and it is 1 to 20, for example, and it is preferably 1 to 15. The hydrocarbon group may be linear or may be branched. The substituent of the hydrocarbon group may include a hetero atom such as a nitrogen atom, an oxygen atom, and a halogen atom. Examples of the substituent of the hydrocarbon group include a hydroxyl group, an amino group, an alkoxy group, and a halogen group.

R⁹ may be a fluorine-containing hydrocarbon group. The fluorine-containing hydrocarbon group may be branched, but preferably it is linear. The fluorine-containing hydrocarbon group may be represented by formula (8) below, for example.

—R¹⁰—Rf (8)

In the formula (8), R¹⁰ is an alkylene group having 1 to 8 carbon atoms and it is preferably an ethylene group. Rf is a perfluoroalkyl group having 1 to 12 carbon atoms. As for Rf, the number of carbon atoms that the perfluoroalkyl group has is preferably 4 to 10, and more preferably 6 to 8.

Specific examples of R⁹ in the formula (7) include a 1H,1H,2H,2H-heptadecafluoro-n-decyl group, a 1H,1H,2H,2H-tridecafluoro-n-octyl group, a methyl group, an ethyl group, a butyl group, a t-butyl group, a hexyl group, a 2-ethylhexyl group, an octyl group, a 2-hydroxyethyl group, a 2-[2-(2-methoxyethoxy)ethoxy]ethyl group, a polyethylene glycol group, and a dimethylaminoethyl group.

Examples of the (meth)acrylamide include (meth)acrylamide, N-isopropyl(meth)acrylamide, dimethylaminopropyl(meth)acrylamide, (meth)acrylamidepropyl trimethylammoniumchloride, and (meth)acrylamide-2-methylpropanesulfonic acid.

Examples of the styrene derivative include styrene, α-methyl styrene, vinylbenzyl chloride, butoxystyrene, vinylaniline, sodium styrenesulfonate, vinylbenzoic acid, vinylpyridine, dimethylaminomethylstyrene, and vinylbenzyl trimethylammonium chloride.

Examples of the olefin include ethylene, propylene, butadiene, butene, and isoprene. Examples of the halogenated olefin include vinyl chloride, vinylidene chloride, and tetrafluoroethylene.

Examples of the vinyl ester include vinyl acetate and vinyl propionate. Examples of the vinyl alcohol include a vinyl alcohol obtained by saponifying the above-mentioned vinyl ester.

Examples of the nitrile include (meth)acrylonitrile.

The monomer group may include one of the monomers mentioned above or two or more of the monomers mentioned above. The monomer group contains, for example, the radical polymerizable monomer as a main component, and preferably it is composed substantially of the radical polymerizable monomer.

The polymerization of the monomer group by the polymerization initiating group is radical polymerization, for example, and preferably it is living radical polymerization. Examples of the living radical polymerization include atom transfer radical polymerization (ATRP), reversible addition-fragmentation chain transfer polymerization (RAFT), and nitroxide-mediated radical polymerization (NMP). Preferably, the living radical polymerization is the ATRP. In the case where the ATRP is carried out, the polymerization initiating group is preferably a halogen group. In the case where the RAFT is carried out, the polymerization initiating group is preferably an azo group. In the case where the NMP is carried out, the polymerization initiating group is preferably a nitroxide group.

The polymerization of the monomer group by the polymerization initiating group can be carried out by the following method, for example. First, a solution A containing the monomer group is prepared. In the case where the monomer group is polymerized by the ATRP, the solution A may contain a transition metal complex as a catalyst.

The transition metal complex includes a transition metal and a ligand. Examples of the transition metal include metals of groups 7 to 11 in the periodic table, and preferably the examples include ruthenium, copper, iron, nickel, rhodium, palladium, and rhenium. Particularly preferably, the transition metal is copper. Examples of the ligand include 1,1,4,7,10,10-hexamethyl triethylenetetramine, tris[2-(dimethylamino)ethyl]amine, N,N,N′,N″,N″-pentamethyl diethylenetriamine, triphenyl phosphine, tributyl phosphine, chlorine, bromine, iodine, indene, fluorene, 2,2′-dipyridine, 4,4′-diheptyl-2,2′-dipyridine, 1,10-phenanthroline, and sparteine. It is possible to prepare the transition metal complex in the solution A by adding separately the ligand and a compound including the transition metal to the solution A.

The solution A may further contain a polymerization initiator. The polymerization initiator may be a compound having the polymerization initiating group mentioned above, and it is preferably the phosphorus compound P1 mentioned above. The polymerization initiator may be 2-bromo-N-hexyl-2-methylpropanamide. In the case where the solution A contains the polymerization initiator, the polymerization of the monomer group proceeds also by the polymerization initiator. A polymer obtained by allowing the monomer group to grow by the polymerization initiator has molecular weights (a number-average molecular weight and a weight-average molecular weight) and molecular weight distribution that are equivalent to those of the polymer chain 3. Therefore, the molecular weights and the molecular weight distribution of the polymer obtained by the polymerization initiator are measured and the obtained values may be assumed as the molecular weights and the molecular weight distribution of the polymer chain 3.

The solution A may further contain or may not contain a solvent. The solvent can be selected suitably depending on a factor such as composition of the monomer group and polymerization conditions. Examples of the solvent include: water; an alcohol such as isopropanol and 1,1,1,3,3,3-hexafluoro-2-propanol; ether such as anisole; and ketone such as acetone. A ratio of a weight of the monomer group with respect to a total value of a weight of the solvent and the weight of the monomer group is not particularly limited, and it is 10 wt % to 100 wt %, for example.

Next, the porous base material 1 is immersed in the solution A. Thereby, the solution A enters into the pore of the porous base material 1 and the monomer group contained in the solution A is in contact with the base layer 2. Here, the porous base material 1 may be subject to a freeze-pump-thaw cycle in the state in which the porous base material 1 is immersed in the solution A. Next, the solution A is heated and thereby the monomer group can be polymerized by the polymerization initiating group included in the base layer 2. A temperature at which the solution A is heated can be adjusted suitably depending on a composition of the solution A, and it is 30° C. to 120° C., for example. A duration for which the solution A is heated is not particularly limited, and it is 0.5 to 48 hours, for example. It is preferable that the monomer group be polymerized under an atmosphere of an inert gas such as a nitrogen gas.

According to the production method of the present embodiment, there is a tendency that a density of the polymer chain 3 with respect to the surface of the porous base material 1 can be adjusted to be high. Per square nanometer of the surface of the porous base material 1, 0.1 or more of the polymer chains 3 are present, for example, and preferably 0.5 or more of the polymer chains 3 are present. The upper limit of the number of the polymer chains 3 per square nanometer of the surface of the porous base material 1 is not particularly limited and it is one, for example.

The number of the polymer chains 3 per square nanometer of the surface of the porous base material 1 can be determined by the following method, for example. First, a weight (an amount of graft (g/g)) of the polymer chain(s) per unit weight of the porous base material 1 per polymerization duration at the time of the polymerization of the monomer group is determined. In the case where the monomer group is composed of a single type of monomers and the monomers include a functional group such as a carbonyl group, the amount of graft can be determined by an infrared spectroscopic analysis (IR), for example. It is possible to determine the amount of graft by, for example, utilizing a calibration curve prepared beforehand by using a mixture of the porous base material 1 that is a source material and a polymer having a composition identical to that of the polymer chain.

Next, a relationship between the amount of graft and the weight of the polymer chain(s) is plotted in a graph and a relational expression (y=ax, for example) of these is calculated. From this relational expression, an amount of increase in the amount of graft in the case where an excess molecule of monomer is polymerized with the polymer chain(s) is calculated. It is possible to calculate the number of the polymer chains 3 per unit weight (1 g) of the porous base material 1 by multiplying a value obtained by dividing the amount of increase by a molar mass of the monomer by an Avogadro constant (6.02×10²³). It is possible to determine the number of the polymer chains 3 per square nanometer of the surface of the porous base material 1 by dividing the calculated value by a specific surface area (nm²/g) of the porous base material 1.

That is, the present invention provides, in another aspect, the porous base material 1 having the pore with the surface 1a modified, including:

the porous base material 1;

the base layer 2 covering the surface 1a of the pore of the porous base material 1; and

the polymer chain 3 bonded to the base layer 2, wherein

0.1 or more of the polymer chains 3 are present per square nanometer of the surface of the porous base material 1.

In the case where the density of the polymer chain 3 with respect to the surface of the porous base material 1 is high, a plurality of the polymer chains 3 can be observed as a layer with an apparatus such as a transmission electron microscope. This layer has a thickness that is not particularly limited and it is 10 nm to 10 mm, for example. It may be 1 mm or less, 100 nm or less, or 50 nm or less.

In the case where the monomer group is polymerized by the living radical polymerization, a molecular weight of the polymer chain 3 can be controlled easily. For example, it is possible to inhibit a variation among molecular weights of a plurality of the polymer chains 3. A molecular weight distribution (a ratio of a weight-average molecular weight with respect a number-average molecular weight) of the polymer chains 3 is not particularly limited and it is 1.5 or less, for example. The molecular weight per the polymer chain 3 is not particularly limited and it is 500 to 500,000, for example.

In the case where the monomer group contains (meth)acrylic ester having a fluorine-containing hydrocarbon group, the obtained polymer chain 3 has a fluorine-containing hydrocarbon group. In the case where the surface 1a of the pore of the porous base material 1 is covered with the polymer chain 3 having a fluorine-containing hydrocarbon group, the porous base material 1 tends to have a significantly enhanced oil repellency. According to the production method of the present embodiment, the density of the polymer chain 3 with respect to the surface of the porous base material 1 can be adjusted to be high. When the density of the polymer chain 3 is high, most of the polymer chains 3 extend in the thickness direction of the base layer 2 and directions of the polymer chains 3 are uniform. Here, the fluorine-containing hydrocarbon group included in the polymer chain 3 is densely present on the surface 1a of the pore. An embodiment in which the fluorine-containing hydrocarbon group is densely present on the surface 1a of the pore is particularly suitable for enhancing the oil repellency of the porous base material 1.

That is, the present invention provides, in another aspect, the porous base material 1 having the pore with the surface 1a modified, including:

the porous base material 1;

the base layer 2 covering the surface 1a of the pore of the porous base material 2; and

the polymer chain 3 bonded to the base layer 2, wherein

the polymer chain 3 has a fluorine-containing hydrocarbon group.

In the case where the polymer chain 3 has a fluorine-containing hydrocarbon group and the porous base material 1 contains a hydrophobic resin, particularly PTFE, the porous base material 1 tends to exhibit a particularly high oil repellency. For example, the porous base material 1 having the pore with the surface 1a modified has an oil repellency at a level at which, when a droplet that is composed of hexane and has a diameter of 5 mm is dropped on the outer surface of the porous base material 1, the droplet fails to penetrate into the outer surface within 30 seconds after being dropped.

That is, the present invention provides, in another aspect, the porous base material 1 having the pore with the surface 1a modified, including: the porous base material 1 containing polytetrafluoroethylene;

the base layer 2 covering the surface 1a of the pore of the porous base material 1; and

the polymer chain 3 bonded to the base layer 2, wherein

when a droplet that is composed of hexane and has a diameter of 5 mm is dropped on the outer surface of the porous base material 1 having the pore with the surface 1a modified, the droplet fails to penetrate into the outer surface within 30 seconds after being dropped.

Generally, it is difficult to introduce a polymer chain into a surface of a porous base material containing a hydrophobic resin, particularly PTFE. However, the production method of the present embodiment makes it possible to easily introduce the polymer chain 3 into the surface 1a of the pore of the porous base material 1 even in the case where the porous base material 1 contains PTFE.

In the production method of the present embodiment, in the case where the polymerization initiating group is introduced into the inorganic layer using the phosphorus compound P1 or the silicon compound S1, the base layer 2 obtained contains a phosphorus atom derived from the phosphorus compound P1 or a silicon atom derived from the silicon compound S1. In the case where the silicon compound S1 is represented by the formula (5) mentioned above, the base layer 2 includes a carbon-silicon bond.

That is, the present invention provides, in another aspect, the porous base material 1 having the pore with the surface 1a modified, including:

the porous base material 1;

the base layer 2 covering the surface 1a of the pore of the porous base material 1; and

the polymer chain 3 bonded to the base layer 2, wherein

the base layer 2 contains at least one selected from the group consisting of a phosphorus atom and a silicon atom.

A gas permeability of the porous base material 1 tends to decrease when the base layer 2 and the polymer chain 3 are introduced into the surface 1a of the pore of the porous base material 1. A level to which the gas permeability of the porous base material 1 decreases can be adjusted suitably by, for example, a factor such as a thickness of the base layer 2 and the molecular weight of the polymer chain 3. A ratio (G2/G1) of a Gurley number G2 (second(s)/100 mL) of the porous base material 1 having the pore with the surface 1a modified with respect to a Gurley number G1 (second(s)/100 mL) of the porous base material 1 itself is not particularly limited, and it is less than 10, for example, and it is preferably less than 5, more preferably less than 2, and still more preferably less than 1.5. In the present description, the “Gurley number” refers to a value determined by Method B (Gurley method) of gas permeability measurement specified in Japanese Industrial Standards (JIS) L 1096 (2010).

By forming the base layer 2 beforehand, the production method of the present embodiment makes it possible to introduce the polymer chain 3 into the surface 1a of the pore of the porous base material 1 without using an energy ray having a large energy. In the production method of the present embodiment, the material of the porous base material 1 is hardly limited because the base layer 2 is used. Furthermore, since the base layer 2 inhibits most of the surface 1a of the pore of the porous base material 1 from being in direct contact with the monomer group, it is possible to inhibit a part of the monomer included in the monomer group from penetrating into the porous base material 1 and swelling the porous base material 1. This makes it possible to inhibit a change in the structure of the porous base material 1. As just described, the production method of the present embodiment is suitable for controlling characteristics of the porous base material 1 by introducing the polymer chain 3 into the surface 1a of the pore of the porous base material 1 while inhibiting a change in the structure of the porous base material itself.

In order to introduce a polymer chain by a conventional method, it is necessary to allow a porous base material to be in direct contact with a monomer group. When most of a surface of a pore of the porous base material is in direct contact with the monomer group, there is a tendency that a part of a monomer included in the monomer group penetrates into the porous base material and the porous base material is swollen. In this case, characteristics, such as mechanical strength and chemical durability, of the porous base material are deteriorated. The deterioration of the characteristics of the porous base material due to the permeation of the monomer is particularly remarkable in the case where the porous base material has a small pore diameter (a pore diameter in nanometer order, for example). The penetration of the monomer changes a structure, such as a shape of the pore, of the porous base material in some cases. In the case where the monomer that has penetrated into the porous base material is polymerized, there is a possibility that the polymer chain fails to be introduced into a surface of the porous base material sufficiently. In the production method of the present embodiment, these problems are unlikely to occur because the base layer 2 is used.

As described above, the production method of the present embodiment tends to be able to provide the porous base material 1 with a high oil repellency by introducing the polymer chain 3 including a fluorine-containing hydrocarbon group into the surface 1a of the pore of the porous base material 1. It should be noted that the characteristics with which the production method of the present embodiment can provide the porous base material 1 is not limited to the oil repellency. The production method of the present embodiment can provide the porous base material 1 with various characteristics depending on the polymer chain 3 to be introduced.

### EXAMPLES

Hereinafter, the present invention will be described in more detail by way of examples. The present invention is not limited to the examples given below.

### [Synthesis of Phosphorus Compound]

First, 2 g of O-phosphorylethanolamine was added to 4.5 mL of a 4 mol/L NaOH aqueous solution and stirred at a room temperature for 10 minutes. Next, while ice-cooling the obtained solution, 4.5 mL of a toluene solution containing 2 mL of 2-bromoisobutylbromide was added to this solution. This solution was stirred for 30 minutes, and further the temperature thereof was raised to a room temperature and the solution continued to be stirred for 2 hours. Next, the stirring was stopped and the obtained solution was centrifuged (5000 rpm) for 20 minutes to separate an organic phase from an aqueous phase. A 2 mol/L HCl aqueous solution was added to the obtained aqueous phase, and then the mixture was subject to an extraction treatment using ethyl acetate. A solvent was distilled off from the resultant extract under a reduced pressure, and further the extract was vacuum-dried to obtain a phosphorus compound that was an orange oil-like substance. This phosphorus compound was (2-bromo-2-methyl-propionylamino)ethyl phosphoric monoester. In the present description, this phosphorus compound is referred to as PA-ATRP in some cases.

### Production Example 1

First, as the porous base material, a PTFE porous membrane A (with an average pore diameter of 3.0 μm, a porosity of 85%, and a thickness of 70 μm) was prepared. Next, by the ALD method, an inorganic layer composed of Al₂O₃ was formed in such a manner as to cover a surface of a pore of the porous base material.

The inorganic layer was formed by the following method using an ALD apparatus (R200 available from Picosun Oy). First, the porous base material was placed in a reaction vessel in the ALD apparatus, and an inside of the reaction vessel was evacuated with a dry-sealed vacuum pump. Next, the porous base material and the reaction vessel were heated to 200° C. Furthermore, a nitrogen gas was introduced into the reaction vessel so that a pressure inside the reaction vessel was 0.5 hPa. Next, a source gas (a precursor of Al₂O₃) was introduced, together with 150 sccm of a nitrogen gas, into the reaction vessel for 0.1 sec (the step i). As the source gas, gaseous trimethylaluminum (TMA available from Air Liquide Japan G.K.) was used. Next, the inside of the reaction vessel was evacuated and further was purged with a nitrogen gas for 2.0 sec (the step ii). Next, an oxidizing gas was introduced, together with 100 sccm of a nitrogen gas, into the reaction vessel for 0.1 sec (the step iii). As the oxidizing gas, water vapor generated by evaporating ultrapure water was used. Next, the inside of the reaction vessel was evacuated and further was purged with a nitrogen gas for 2.0 sec (the step iv). The cycle of the steps I to iv was repeated 400 times to form the inorganic layer. A small piece of silicon wafer was placed beforehand in the reaction vessel in the ALD apparatus. Therefore, the inorganic layer was formed also on a surface of this small piece of silicon wafer through the above-mentioned procedure. A thickness of the inorganic layer formed on the surface of the small piece of silicon wafer was measured with a stylus-type coating thickness gauge. The obtained measurement value was assumed as a thickness of the inorganic layer formed on the surface of the pour of the porous base material. The thickness of the inorganic layer was 42.3 nm.

Next, an ethanol solution containing the PA-ATRP at a concentration of 10 mmol/L was prepared. Next, the porous base material after being treated with the ALD was immersed in this ethanol solution for 24 hours under a room temperature (23° C.). Thereby, a reaction between the PA-ATRP and a hydroxyl group present on a surface of the inorganic layer proceeded and a polymerization initiating group was introduced into the inorganic layer. Next, the porous base material was washed with ethanol 3 times and further washed with ion exchanged water 3 times. This porous base material was vacuum-dried under a room temperature to obtain a porous base material of Production Example 1 having a pore with a surface on which a base layer is formed.

A specific surface area of the porous base material with the base layer formed thereon was measured by the BET adsorption method by nitrogen gas adsorption. Furthermore, the number of Br included in the base layer was determined by the following method. First, the porous base material with the base layer formed thereon was placed on a ceramic board and weighed. Next, this porous base material was burned using an automatic specimen burner. A gas generated at that time was collected in 10 mL of an absorbing solution. Ultrapure water was added to this absorbing solution to adjust the amount to 15 mL and the mixture was subject to a quantitative analysis by ion chromatograph (IC). Thereby, the number of the polymerization initiating groups (Br) included in the base layer was determined. Based on the obtained result, a density of the polymerization initiating group (Br) with respect to a surface of the porous base material was calculated. The density of the polymerization initiating group was 2.4 per square nanometer of the surface of the porous base material.

### Production Examples 2 to 8

A porous base material of each of Production Examples 2 to 8 was obtained in the same manner as in Production Example 1, except that the type of the porous base material and the number of cycles of the steps i to iv when the inorganic layer was formed were changed to those shown in Table 1 and that the temperature at which the porous base material and the reaction vessel were heated when the inorganic layer was formed was changed to 100° C. A PTFE porous membrane B had an average pore diameter of 0.1 μm, a porosity of 81%, and a thickness of 70 μm.

TABLE 1

| | | Method for | | |
|---|---|---|---|---|
| | | forming | The number | Thickness of |
| Production | Type of porous | inorganic | of cycles of | inorganic layer |
| Example | base material | layer | steps i to iv (times) | (nm) (*1) |
| 1 | PTFE porous | ALD | 400 | 42.3 |
| | membrane A | | | |
| 2 | PTFE porous | ALD | 100 | 9.0 |
| | membrane B | | | |
| 3 | PTFE porous | ALD | 200 | 17.9 |
| | membrane B | | | |
| 4 | PTFE porous | ALD | 300 | 26.9 |
| | membrane B | | | |
| 5 | PTFE porous | ALD | 400 | 35.8 |
| | membrane B | | | |
| 6 | PTFE porous | ALD | 600 | 53.8 |
| | membrane B | | | |
| 7 | PTFE porous | ALD | 800 | 71.7 |
| | membrane B | | | |
| 8 | PTFE porous | ALD | 1000 | 89.6 |
| | membrane B | | | |

(*1) The thickness of the inorganic layer formed on the surface of the small piece of silicon wafer.

### Production Example 9

First, as the porous base material, the PTFE porous membrane B (an average pore diameter of 0.1 μm, a porosity of 81%, and a thickness of 70 μm) was prepared. Next, an inorganic layer composed of Al₂O₃ was formed by the spattering method in such a manner as to cover a surface of a pore near an outer surface of the porous base material.

The inorganic layer was formed by the following method using a vacuum sputtering apparatus (SH350 available from ULVAC, Inc.). First, the porous base material was placed in the vacuum sputtering apparatus and an inside of the apparatus was evacuated so as to achieve an ultimate vacuum of 5×10⁻⁴ Pa. Next, Ar and O₂ were introduced into the apparatus at a flow ratio of Ar:O₂=87:13 and thereby the inside of the apparatus was adjusted to have a vacuum atmosphere of 0.3 Pa. Next, a RF magnetron sputtering method (0.25 kW of RF power) using aluminum as a target was carried out under the vacuum atmosphere to form an inorganic layer composed of Al₂O₃. A small piece of silicon wafer was placed in the vacuum sputtering apparatus beforehand. Therefore, the inorganic layer was formed also on a surface of this small piece of silicon wafer through the above-mentioned procedure. A thickness of the inorganic layer formed on the surface of the small piece of silicon wafer was measured with a stylus-type coating thickness gauge. The obtained measurement value was assumed as a thickness of the inorganic layer formed on the surface of the pour of the porous base material. The thickness of the inorganic layer was 14.1 nm.

Next, an ethanol solution containing the PA-ATRP at a concentration of 10 mmol/L was prepared. Next, the porous base material that had been subject to the sputtering treatment was immersed in this ethanol solution for 24 hours under a room temperature (23° C.). Thereby, a reaction between the PA-ATRP and a hydroxyl group present on a surface of the inorganic layer proceeded and a polymerization initiating group was introduced into the inorganic layer. Next, the porous base material was washed with ethanol 3 times and further washed with ion exchanged water 3 times. This porous base material was vacuum-dried under a room temperature to obtain a porous base material of Production Example 9 having a pore with a surface on which a base layer was formed.

### Production Examples 10 and 11

A porous base material of each of Production Examples 10 and 11 was obtained in the same manner as in Production Example 9, except that the porous base material was subject to the sputtering treatment in such a manner that the thicknesses of the inorganic layer was the value shown in Table 2.

### Production Example 12

First, as the porous base material, the PTFE porous membrane B (an average pore diameter of 0.1 μm, a porosity of 81%, and a thickness of 70 μm) was prepared. Next, an inorganic layer composed of SiO₂ was formed by the spattering method in such a manner as to cover a surface of a pore near an outer surface of the porous base material.

The inorganic layer was formed by the following method using the vacuum sputtering apparatus (SH350 available from ULVAC, Inc.). First, the porous base material was placed in the vacuum sputtering apparatus and an inside of the apparatus was evacuated so as to achieve an ultimate vacuum of 5×10⁻⁴ Pa. Next, Ar and O₂ were introduced into the apparatus at a flow ratio of Ar:O₂=80:20 and thereby the inside of the apparatus was adjusted to have a vacuum atmosphere of 0.3 Pa. Next, a RF magnetron sputtering method (0.25 kW of RF power) using silicon as a target was carried out under a vacuum atmosphere to form an inorganic layer composed of SiO₂. A small piece of silicon wafer was placed in the vacuum sputtering apparatus beforehand. Therefore, the inorganic layer was formed also on a surface of this small piece of silicon wafer through the above-mentioned procedure. A thickness of the inorganic layer formed on the surface of the small piece of silicon wafer was measured with a stylus-type coating thickness gauge. The obtained measurement value was assumed as a thickness of the inorganic layer formed on the surface of the pour of the porous base material. The thickness of the inorganic layer was 21 nm.

Next, an ethanol solution containing a silane-coupling-agent-type ATRP initiator (3-(triethoxysilyl)propyl 2-bromo-2-methylpropanoate available from Tokyo Chemical Industry Co., Ltd.) at a concentration of 10 mmol/L was prepared. Next, the porous base material that had been subject to the sputtering treatment was immersed in this ethanol solution for 24 hours under a room temperature (23° C.). Thereby, a reaction between the silane-coupling-agent-type ATRP initiator and a hydroxyl group present on a surface of the inorganic layer proceeded and a polymerization initiating group was introduced into the inorganic layer. Next, the porous base material was washed with ethanol 3 times and further washed with ion exchanged water 3 times. This porous base material was vacuum-dried under a room temperature to obtain a porous base material of Production Example 12 having a pore with a surface on which a base layer was formed.

### Production Example 13

First, as the porous base material, the PTFE porous membrane B (an average pore diameter of 0.1 μm, a porosity of 81%, and a thickness of 70 μm) was prepared. Next, an inorganic layer was formed by the spattering method in such a manner as to cover a surface of a pore near an outer surface of the porous base material. In the Production Example 13, the inorganic layer was composed of a first layer composed of SiO₂ and a second layer composed of Al₂O₃.

The inorganic layer was formed by the following method using the vacuum sputtering apparatus (SH350 available from ULVAC, Inc.). First, the porous base material was placed in the vacuum sputtering apparatus and an inside of the apparatus was evacuated so as to achieve an ultimate vacuum of 5×10⁻⁴ Pa. Next, Ar and O₂ were introduced into the apparatus at a flow ratio of Ar:O₂=80:20 and thereby the inside of the apparatus was adjusted to have a vacuum atmosphere of 0.3 Pa. Next, a RF magnetron sputtering method (0.25 kW of RF power) using silicon as a target was carried out under a vacuum atmosphere to form the first layer composed of SiO₂. A small piece of silicon wafer was placed in the vacuum sputtering apparatus beforehand. Therefore, the first layer was formed also on a surface of this small piece of silicon wafer through the above-mentioned procedure. A thickness of the first layer formed on the surface of the small piece of silicon wafer was measured with a stylus-type coating thickness gauge. The obtained measurement value was assumed as a thickness of the first layer formed on the surface of the pour of the porous base material. The thickness of the first layer was 21.0 nm.

Next, the porous base material with the first layer formed thereon was placed in the vacuum sputtering apparatus and the inside of the apparatus was evacuated so as to achieve an ultimate vacuum of 5×10⁻⁴ Pa. Next, Ar and O₂ were introduced into the apparatus at a flow ratio of Ar:O₂=87:13 and thereby the inside of the apparatus was adjusted to have a vacuum atmosphere of 0.3 Pa. Next, a RF magnetron sputtering method (0.25 kW of RF power) using aluminum as a target was carried out under a vacuum atmosphere to form the second layer composed of Al₂O₃ on the first layer. Thereby, an inorganic layer composed of the first layer and the second layer was obtained. A thickness of the second layer measured by the same method as that used for the first layer was 8.8 nm.

Next, an ethanol solution containing the PA-ATRP at a concentration of 10 mmol/L was prepared. Next, the porous base material that had been subject to the sputtering treatment was immersed in this ethanol solution for 24 hours under a room temperature (23° C.). Thereby, a reaction between the PA-ATRP and a hydroxyl group present on a surface of the inorganic layer proceeded and a polymerization initiating group was introduced into the inorganic layer. Next, the porous base material was washed with ethanol 3 times and further washed with ion exchanged water 3 times. This porous base material was vacuum-dried under a room temperature to obtain a porous base material of Production Example 13 having a pore with a surface on which a base layer was formed.

TABLE 2

| | | Method for | Material of | Thickness of |
|---|---|---|---|---|
| Production | Type of porous | forming | inorganic | inorganic layer |
| Example | base material | inorganic layer | layer | (nm) (*1) |
| 9 | PTFE porous | Sputtering | Al₂O₃ | 14.1 |
| | membrane B | | | |
| 10 | PTFE porous | Sputtering | Al₂O₃ | 32.9 |
| | membrane B | | | |
| 11 | PTFE porous | Sputtering | Al₂O₃ | 50.4 |
| | membrane B | | | |
| 12 | PTFE porous | Sputtering | SiO₂ | 21 |
| | membrane B | | | |
| 13 | PTFE porous | Sputtering | SiO₂/Al₂O₃ | 21.0/8.8 (*2) |
| | membrane B | | | |

(*1) The thickness of the inorganic layer formed on the surface of the small piece of silicon wafer.
(*2) The thickness of the first layer/the thickness of the second layer.

### Example 1

The porous base material of the Production Example 1, a monomer group, a polymerization initiator, a compound including a transition metal, a ligand and a solvent were put in a polymerization tube. The porous base material was cut into a size of approximately 2 cm×3 cm beforehand. The monomer group was composed of methyl methacrylate (MMA). As the polymerization initiator, 2-bromo-N-hexyl-2-methylpropanamide was used. As the compound including a transition metal, CuBr was used. As the ligand, 1,1,4,7,10,10-hexamethyl triethylenetetramine (HMTETA) was used. As the solvent, anisole (PhOMe) was used. A molar ratio R1 of the monomer group, the polymerization initiator, the compound including a transition metal, and the ligand was 1000/1/1/1. A ratio R2 of a weight of the monomer group with respect to a total value of a weight of the solvent and the weight of the monomer group was 20 wt %.

Next, an inside of the polymerization tube was subject to a freeze-pump-thaw cycle 3 times and then filled with a nitrogen gas. Next, the polymerization tube was heated to 80° C. to polymerize the monomer group. After the polymerization was completed, air was injected into the resultant reaction solution to bubble it. Thereby, radicals in the reaction solution were eliminated. The porous base material was taken out from the polymerization tube and washed with a washing fluid 3 times. As the washing fluid, acetone was used. This porous base material was dried in a drying oven at 60° C. for 1 hour to obtain a porous base material of Example 1 having a pore with a surface modified.

### Examples 2 to 20

A porous base material of each of Examples 2 to 20 was obtained in the same manner as in Example 1, except that the type of the porous base material, the monomer of which the monomer group is composed, the solvent, the ligand, the molar ratio R1, the ratio R2, the reaction temperature, the reaction duration, and the washing fluid were changed to those shown in Table 3.

When a cross-section of the porous base material of each of Examples 1 to 20 was observed with a transmission electron microscope, it was found that a polymer chain had been introduced into a surface of a pore of the porous base material. As for each of Examples 3 to 5, when a droplet composed of water was dropped on an outer surface of the porous base material using a pipet, the droplet penetrated into the porous base material. This reveals that the porous base material of each of Examples 3 to 5 was hydrophilized.

TABLE 3

| | | | | | Molar | Ratio | | | |
|---|---|---|---|---|---|---|---|---|---|
| | Porous | | | | ratio | R2 | Reaction | Reaction | |
| | base | | | | R1 | (wt %) | temperature | duration | Washing |
| Example | material | Monomer | Solvent | Ligand | (*1) | (*2) | (° C.) | (h) | solvent |
| 1 | Production | MMA | PhOMe | HMTETA | 1000/1/1/1 | 20 | 80 | 8 | Acetone |
| | Example 1 | | | | | | | | |
| 2 | Production | St | PhOMe | Me6TREN | 1000/1/1/1 | 20 | 80 | 8 | Acetone |
| | Example 1 | | | | | | | | |
| 3 | Production | HEMA | H₂O | HMTETA | 100/1/1/1 | 50 | 30 | 4 | H₂O |
| | Example 1 | | | | | | | | |
| 4 | Production | TEGMEAc | IPA | Me6TREN | 100/1/1/1 | 50 | 60 | 16 | MeOH |
| | Example 1 | | | | | | | | |
| 5 | Production | BLEMMER | IPA | Me6TREN | 100/1/1/1 | 50 | 60 | 16 | MeOH |
| | Example 1 | PE-90 | | | | | | | |
| 6 | Production | NIPAm | Acetone | PMDETA | 1000/1/1/1 | 50 | 70 | 18 | Acetone |
| | Example 1 | | | | | | | | |
| 7 | Production | PFAc6 | HFlP | Me6TREN | 100/1/1/1 | 50 | 60 | 16 | HFlP |
| | Example 1 | | | | | | | | |
| 8 | Production | PFAc8 | Neat | Me6TREN | 1000/1/1/1 | 100 | 60 | 16 | HFlP |
| | Example 1 | | | | | | | | |
| 9 | Production | PFAc8 | Neat | Me6TREN | 1000/1/1/1 | 100 | 60 | 16 | HFlP |
| | Example 2 | | | | | | | | |
| 10 | Production | PFAc8 | Neat | Me6TREN | 1000/1/1/1 | 100 | 60 | 16 | HFlP |
| | Example 3 | | | | | | | | |
| 11 | Production | PFAc8 | Neat | Me6TREN | 1000/1/1/1 | 100 | 60 | 16 | HFlP |
| | Example 4 | | | | | | | | |
| 12 | Production | PFAc8 | Neat | Me6TREN | 1000/1/1/1 | 100 | 60 | 16 | HFlP |
| | Example 5 | | | | | | | | |
| 13 | Production | PFAc8 | Neat | Me6TREN | 1000/1/1/1 | 100 | 60 | 16 | HFlP |
| | Example 6 | | | | | | | | |
| 14 | Production | PFAc8 | Neat | Me6TREN | 1000/1/1/1 | 100 | 60 | 16 | HFlP |
| | Example 7 | | | | | | | | |
| 15 | Production | PFAc8 | Neat | Me6TREN | 1000/1/1/1 | 100 | 60 | 16 | HFlP |
| | Example 8 | | | | | | | | |
| 16 | Production | PFAc8 | Neat | Me6TREN | 1000/1/1/1 | 100 | 60 | 16 | HFlP |
| | Example 9 | | | | | | | | |
| 17 | Production | PFAc8 | Neat | Me6TREN | 1000/1/1/1 | 100 | 60 | 16 | HFlP |
| | Example 10 | | | | | | | | |
| 18 | Production | PFAc8 | Neat | Me6TREN | 1000/1/1/1 | 100 | 60 | 16 | HFlP |
| | Example 11 | | | | | | | | |
| 19 | Production | PFAc8 | Neat | Me6TREN | 1000/1/1/1 | 100 | 60 | 16 | HFlP |
| | Example 12 | | | | | | | | |
| 20 | Production | PFAc8 | Neat | Me6TREN | 1000/1/1/1 | 100 | 60 | 16 | HFlP |
| | Example 13 | | | | | | | | |

(*1) Molar ratio of the monomer group, the polymerization initiator, the compound including a transition metal, and the ligand.
(*2) The ratio of a weight of the monomer group with respect to a total value of a weight of the solvent and the weight of the monomer group.
The abbreviations in Table 3 are as follows.
MMA: Methyl methacrylate (available from Tokyo Chemical Industry Co., Ltd.)
St: Styrene (available from Tokyo Chemical Industry Co., Ltd.)
HEMA: 2-hydroxyethyl methacrylate (available from Tokyo Chemical Industry Co., Ltd.)
TEGMEAc: 2-[2-(2-methoxyethoxy)ethoxy]ethyl acrylate (available from Tokyo Chemical Industry Co., Ltd.)
BLEMMER PE-90: Polyethyleneglycol-monomethacrylate (available from NOF CORPORATION)
NIPAm: N-isopropylacrylamide
PFAc8: 1H,1H,2H,2H-heptadecafluoro-n-decyl acrylate (available from Tokyo Chemical Industry Co., Ltd.)
PFAc6: 1H,1H,2H,2H-tridecafluoro-n-octyl acrylate (available from Tokyo Chemical Industry Co., Ltd.)
PhOMe: Anisole (available from Tokyo Chemical Industry Co., Ltd.)
H₂O: Ultrapure water
IPA: Isopropanol (available from FUJIFILM Wako Pure Chemical Corporation)
HFlP: 1,1,1,3,3,3-hexafluoro-2-propanol
Neat: No solvent
HMTETA: 1,1,4,7,10,10-hexamethyltriethylenetetramine
Me6TREN: Tris[2-(dimethylamino)ethyl]amine
PMDETA: N,N,N′,N″,N″-pentamethyldiethylenetriamine
MeOH: Methanol (available from FUJIFILM Wako Pure Chemical Corporation)

### Comparative Example 1

A monomer group, a polymerization initiator, a compound including a transition metal, a ligand, and a solvent were put in a polymerization tube. The monomer group was composed of the 1H,1H,2H,2H-heptadecafluoro-n-decyl acrylate (PFAc8). As the polymerization initiator, the PA-ATRP was used. As the compound including a transition metal, copper bromide (I) (CuBr) was used. As the ligand, the tris[2-(dimethylamino)ethyl]amine (Me6TREN) was used. As the solvent, the 1,1,1,3,3,3-hexafluoro-2-propanol (HFIP) was used. The molar ratio R1 of the monomer group, the polymerization initiator, the compound including a transition metal, and the ligand was 100/1/1/1. The ratio R2 of a weight of the monomer group with respect to a total value of a weight of the solvent and the weight of the monomer group was 50 wt %.

Next, an inside of the polymerization tube was subject to a freeze-pump-thaw cycle 3 times and then filled with a nitrogen gas. Next, the polymerization tube was heated to 60° C. to polymerize the monomer group. After the polymerization was completed, air was injected into the resultant reaction solution to bubble it. Thereby, radicals in the reaction solution were eliminated. The obtained reaction solution was subject to alumina column chromatography to remove a transition metal complex from the reaction solution. Next, the resultant solution was subject to a reprecipitation treatment using methanol to obtain a target fluorine polymer.

Next, the obtained fluorine polymer was dissolved in a fluorine solvent (CELEFIN (registered trademark) 1233Z available from Central Glass Co., Ltd.). A concentration of the fluorine polymer in the obtained solution was 1 wt %. The porous base material (the PTFE porous membrane A) cut into a square of approximately 5 cm by 5 cm was immersed in this solution for 10 seconds. This porous base material was taken out from the solution and air-dried for 30 minutes. Next, the porous base material was dried in a drying oven at 80° C. for 1 hour. Thereby, a porous base material of Comparative Example 1 having a pore with a surface treated with the fluorine polymer was obtained.

### Comparative Example 2

A porous base material of Comparative Example 2 having a pore with a surface treated with the fluorine polymer was obtained in the same manner as in Comparative Example 1, except that the PTFE porous membrane B was used as the porous base material.

### Comparative Example 3

First, the porous base material (the PTFE porous membrane A) was irradiated with an electron ray of 100 kGy under a nitrogen atmosphere at a room temperature. After being irradiated with the electron ray, the porous base material was stored under an atmosphere at −60° C.

Next, an HFIP solution containing the 1H,1H,2H,2H-heptadecafluoro-n-decyl acrylate (PFAc8 available from Tokyo Chemical Industry Co., Ltd.) at a concentration of 50 wt % was prepared. 50 mL of the solution was added into a polymerization tube and was bubbled for 2 hours using a nitrogen gas. Thereby, a monomer solution from which oxygen in the system had been removed was obtained.

Next, the porous base material irradiated with the electron ray was cut into a square of approximately 5 cm by 5 cm and immersed in the above-mentioned monomer solution. Next, the monomer solution was heated for 16 hours by maintaining the temperature thereof at 60° C. Next, the porous base material was taken out from the solution and washed 3 times using the HFIP. Next, the porous base material was dried in a drying oven at 60° C. for 1 hour. Thereby, a porous base material of Comparative Example 3 having a pore with a surface on which the PFAc8 had been graft-polymerized was obtained. The porous base material of Comparative Example 3 was extremely fragile. When a surface of the porous base material of Comparative Example 3 was observed with an electron microscope, it was found that many of fibrils of which the porous base material was composed were cut.

### Comparative Example 4

The PTFE porous membrane B that had been untreated was used as a porous base material of Comparative Example 4.

### Comparative Example 5

A porous base material of Comparative Example 5 having a pore with a surface treated with the fluorine polymer was obtained in the same manner as in Comparative Example 1, except that the concentration of the fluorine polymer in the solution for treating the surface of the pore of the porous base material was changed to 0.1 wt %.

### Comparative Example 6

A porous base material of Comparative Example 6 having a pore with a surface treated with the fluorine polymer was obtained in the same manner as in Comparative Example 1, except that the PTFE porous membrane B was used as the porous base material and that the concentration of the fluorine polymer in the solution for treating the surface of the pore of the porous base material was changed to 0.1 wt %.

### [Evaluation on Oil Repellency]

The porous base materials of Examples and Comparative Examples were subject to an oil repellency test. The oil repellency test was conducted in accordance with “Oil Repellency: Hydrocarbon Resistance Test” specified in AATCC118-1997. Specifically, a droplet that was composed of an organic solvent and had a diameter of 5 mm was dropped on the outer surface of each of the porous base materials using a pipet and checked visually for occurrence of penetration of the droplet. As the organic solvent, hexadecane, tetradecane, dodecane, decane, octane, heptane, and hexane were used. As for the penetration of the droplet, the droplet was determined to have “penetrated” when the droplet was absorbed by the porous base material or the penetration of the droplet changed a color tone of the porous base material.

Table 4 shows the organic solvents used for the oil repellency test as well as the evaluation criteria for the cases in which the organic solvent failed to penetrate. The oil repellency test was conducted using the organic solvents shown in Table 4 in the descending order of their surface tensions. Table 5 shows, as the evaluation results of the oil repellency test, the evaluation criteria for the organic solvent with a lowest surface tension out of the organic solvents that failed to penetrate into the porous base material. For example, according to Table 5, it means that the droplet of octane failed to penetrate into the porous base material with the evaluation result of 7 while the droplet of heptane penetrated thereinto. It means that the droplet of hexane failed to penetrate into the porous base material with the evaluation result of 9.

### [Evaluation on Decrease in Gas Permeability]

The porous base materials of Examples and Comparative Examples were evaluated for decrease in gas permeability from before to after the surface of the pore was modified. Specifically, a ratio (G2/G1) of a Gurley number G2 (second(s)/100 mL) of the porous base material having a pore with a surface modified with respect to a Gurley number G1 (second(s)/100 mL) of the porous base material itself was calculated. Table 5 shows the results. The criteria for evaluating the decrease in gas permeability are as follows.

A: G2/G1 is 1 or more and less than 1.5.
B: G2/G1 is 1.5 or more and less than 2.
C: G2/G1 is 2 or more and less than 5.
D: G2/G1 is 5 or more and less than 10.
E: G2/G1 is ten or more.

TABLE 4

| Criteria for | | Surface |
|---|---|---|
| oil repellency | Organic | tension |
| evaluation | solvent | (dyn/cm) |
| 3 | Hexadecane | 29 |
| 4 | Tetradecane | 27 |
| 5 | Dodecane | 24.5 |
| 6 | Decane | 24 |
| 7 | Octane | 21 |
| 8 | Heptane | 19.5 |
| 9 | Hexane | 18 |

TABLE 5

| Porous | Results of oil | Results of gas |
|---|---|---|
| base material | repellency evaluation | permeability evaluation |
| Example 7 | 9 | B |
| Example 8 | 9 | B |
| Example 9 | 9 | C |
| Example 10 | 9 | C |
| Example 11 | 9 | C |
| Example 12 | 9 | C |
| Example 13 | 9 | D |
| Example 14 | 9 | E |
| Example 15 | 9 | E |
| Example 16 | 7 | B |
| Example 17 | 7 | A |
| Example 18 | 7 | B |
| Example 19 | 7 | B |
| Example 20 | 7 | A |
| Comparative Example 1 | 5 | E |
| Comparative Example 2 | 5 | E |
| Comparative Example 3 | — | — |
| Comparative Example 4 | <3 | — |
| Comparative Example 5 | 4 | B |
| Comparative Example 6 | 4 | B |

As described above, it is generally difficult to introduce a polymer chain into a surface of a porous base material containing PTFE. However, as shown by Examples 1 to 20, the production method of the present embodiment made it possible to easily introduce a polymer chain into a surface of a pore of a porous base material containing PTFE.

Furthermore, as shown in Table 5, the porous base material of each of Examples 7 to 20 having a pore with a surface into which the polymer chain having a fluorine-containing hydrocarbon group was introduced by the production method of the present embodiment had an oil repellency higher than those of the porous base materials of Comparative Examples 1, 2, 5, and 6 that had been subject to the oil repellent treatment by the conventional method. Table 5 also reveals that Examples each were provided with an oil repellency higher than those of Comparative Examples as long as Examples and Comparative Examples were equivalent in terms of the decrease in gas permeability. The production method of the present embodiment is suitable for providing a porous base material with oil repellency while inhibiting the gas permeability from decreasing due to partial blocking or narrowing of the pore of the porous base material.

As shown in Table 5, the decrease in gas permeability from before to after the surface of the pore was modified was inhibited particularly on the porous base materials of Examples 16 to 20 each having the inorganic layer produced by the spattering method.

### INDUSTRIAL APPLICABILITY

A porous base material obtained by the production method of the present invention can be used for various applications, such as a sound-transmitting membrane, a gas-permeable membrane, a separation membrane, an ion exchange membrane, a diaphragm, a catalyst, a liquid absorber, and a medical material, depending on its function.

1. A method for producing a porous base material having a pore with a surface modified, comprising:
forming a base layer having a polymerization initiating group in such a manner as to cover a surface of a pore of a porous base material; and
allowing a monomer group to be in contact with the base layer and thereby polymerizing the monomer group by the polymerization initiating group.

2. The production method according to claim 1, wherein the polymerization of the monomer group by the polymerization initiating group is living radical polymerization.

3. The production method according to claim 1, further comprising forming an inorganic layer in such a manner as to cover the surface of the pore, wherein
the polymerization initiating group is introduced into the inorganic layer to form the base layer.

4. The production method according to claim 3, wherein the inorganic layer is formed by a physical deposition method or a chemical deposition method.

5. The production method according to claim 3, wherein the inorganic layer is formed by an atomic layer deposition method.

6. The production method according to claim 3, wherein the inorganic layer is formed by a spattering method.

7. The production method according to claim 3, wherein the inorganic layer contains at least one selected from the group consisting of Al₂O₃, SiO₂, and TiO₂.

8. The production method according to claim 3, wherein at least one selected from the group consisting of a phosphorus compound including the polymerization initiating group and a silicon compound including the polymerization initiating group is allowed to react with a hydroxyl group present on a surface of the inorganic layer to introduce the polymerization initiating group into the inorganic layer.

9. The production method according to claim 1, wherein the porous base material contains a hydrophobic resin.

10. The production method according to claim 1, wherein the monomer group contains (meth)acrylic ester having a fluorine-containing hydrocarbon group.

11. A porous base material having a pore with a surface modified, comprising:
a porous base material;
a base layer covering a surface of a pore of the porous base material; and
a polymer chain bonded to the base layer, wherein
the base layer contains at least one selected from the group consisting of a phosphorus atom and a silicon atom.

12. The porous base material having a pore with a surface modified according to claim 11, wherein the base layer includes a carbon-silicon bond.

13. A porous base material having a pore with a surface modified, comprising:
a porous base material;
a base layer covering a surface of a pore of the porous base material; and
a polymer chain bonded to the base layer, wherein
the polymer chain has a fluorine-containing hydrocarbon group.

14. The porous base material having a pore with a surface modified according to claim 11, wherein the porous base material contains a hydrophobic resin.

15. The porous base material having a pore with a surface modified according to claim 11, wherein the porous base material contains polytetrafluoroethylene.

16. A porous base material having a pore with a surface modified, comprising:
a porous base material containing polytetrafluoroethylene;
a base layer covering a surface of a pore of the porous base material; and
a polymer chain bonded to the base layer, wherein
when a droplet that is composed of hexane and has a diameter of 5 mm is dropped on an outer surface of the porous base material having the pore with the surface modified, the droplet fails to penetrate into the outer surface within 30 seconds after being dropped.

17. The porous base material having a pore with a surface modified according to claim 13, wherein the porous base material contains a hydrophobic resin.

18. The porous base material having a pore with a surface modified according to claim 13, wherein the porous base material contains polytetrafluoroethylene.
